(19) United States
(12) Patent Application Publication
(10) Pub. No.: US 2013/0181227 A1
(43) Pub. Date: Jul. 18, 2013

(54) LED Package with Slanting Structure and Method of the Same

(71) Applicant: Wen Kun YANG, Hsin-Chu (TW)

(72) Inventor: Wen Kun YANG, Hsin-Chu (TW)

(73) Assignee: KING DRAGON INTERNATIONAL INC., Tortola (BV)

(21) Appl. No.: 13/348,787

(22) Filed: Jan. 12, 2012

(51) Int. Cl. H01L 33/50; H01L 33/62; H01L 33/60

(52) U.S. Cl. 257/77; 257/98; 257/76; 257/E33.073; 257/E33.072; 257/E33.066

(57) ABSTRACT

The LED package comprises a substrate with a first conductive type through-hole and a second conductive type through-hole through the substrate; a reflective layer formed on an upper surface of the substrate; a LED die having first conductive type pad and second conductive type pad, wherein the first conductive type pad is aligned with the first conductive type through-hole; a slanting structure of dielectric layer formed adjacent at least one side of the LED die for carrying conductive traces; a conductive trace formed on upper surface of the slanting structure to offer path between the second conductive type pad and the conductive type through-hole; and a refilling material within the first conductive type through-hole and second conductive type through-hole.

### FIELD OF THE INVENTION

This invention relates to a LED package, and more particularly to LED package with slanting structure adjacent to the die.

### DESCRIPTION OF THE PRIOR ART

High performance integrated circuit (IC) packages are well known in the art. Improvements in IC packages are driven by industry demands for increased thermal and electrical performance and decreased size and cost of manufacture. In the field of LED devices, it is required to be package as the IC device. The die density is increased and the device dimension is reduced, continuously. The demand for the packaging techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support. . . and so on. As a semiconductor become more complicated, the traditional package technique, for example lead frame package, flex package, rigid package technique, can't meet the demand of producing smaller chip with high density elements on the chip.

The package can have a core made of a common material such as glass epoxy, and can have additional layers laminated onto the core. Patterns may be built in the metal or conductive layer through various etching processes such as wet etching which are known in the art and will not be described further herein. Input/Output functions are typically accomplished using metal traces between the layers. Each trace is generated by its geometry and location on the package. Due to the manufacturing technology and material requirements, packages having built-up layers often include a number of degassing holes in the metal layers. Degassing holes allow gas to be evaporated during the manufacture of the package so that bubbles do not form in the package. Traces may be routed over or under the degassing holes, or around the degassing holes, or a combination thereof. Since the traces are not in the same location on the package, and pass over varying amounts of non-metal areas caused by degassing holes in the metal layers, the traces have an impedance variation, or mismatch. These additional layers are also known as “built-up” layers. The built-up layers are typically formed from alternating layers of dielectric material and conductive material.

Ibbetson disclosed a LED package, entitled “Chip-scale methods for packaging light emitting devices and chip-scale packaged light emitting devices”. The packaged light emitting device includes a carrier substrate having a top surface and a bottom surface, first and second conductive vias extending from the top surface of the substrate to the bottom surface of the substrate, and a bond pad on the top surface of the substrate in electrical contact with the first conductive via. A diode having first and second electrodes is mounted on the bond pad with the first electrode is in electrical contact with the bond pad. A passivation layer is formed on the diode, exposing the second electrode of the diode. A conductive trace is formed on the top surface of the carrier substrate in electrical contact with the second conductive via and the second electrode. The conductive trace is on and extends across the passivation layer to contact the second electrode. Methods of packaging light emitting devices include providing an epiwafer including a growth substrate and an epitaxial structure on the growth substrate, bonding a carrier substrate to the epitaxial structure of the epiwafer, forming a plurality of conductive vias through the carrier substrate, defining a plurality of isolated diodes in the epitaxial structure, and electrically connecting at least one conductive via to respective ones of the plurality of isolated diodes.

However, the package is too thick and structure is also too complicated.

### SUMMARY OF THE INVENTION

An object of the present invention is to provide a LED package with slanting structure. The present invention provides a LED structure with P, N type through holes from the top surface to lower surface, thereby improving the efficiency and scale down the size of the device.

Another object of the present invention is to provide a convenient, cost-effective method for manufacturing a LED package (chip assembly).

In one aspect, the LED package comprises a substrate with a first conductive type through-hole and a second conductive type through-hole through the substrate; a reflective layer formed on an upper surface of the substrate; a LED die having first conductive type pad and second conductive type pad, wherein the first conductive type pad is aligned with the first conductive type through-hole; a slanting structure of dielectric layer formed adjacent at least one side of the LED die for carrying conductive traces; a conductive trace formed on upper surface of the slanting structure to offer path between the second conductive type pad and the conductive type through-hole; and a refilling material within the first conductive type through-hole and second conductive type through-hole.

The LED package further comprises a lens formed over the upper surface of the substrate to cover the LED die. The LED package further comprises a first conductive type terminal pad under the substrate and coupled to the first conductive type pad; a first type terminal pad under the substrate and coupled to the first conductive type pad. The LED die comprises an P/N film formed over the LED substrate. The reflective layer includes organic layer, metal or alloy; wherein the reflective layer is formed by sputtering, or E-plating Ag, Al or Au. The LED die includes sapphire, Si, SiC, AlN type substrate. The lens has phosphor material inside. The refilling material for the first conductive type through-hole and a second conductive type through-hole is formed by Alumina, Titanium, Copper, Nicole or Silver. The refilling material is formed by Cu/Ni/Au.

### BRIEF DESCRIPTION OF THE DRAWINGS

FIG. 1 is cross-sectional views showing a LED chip assembly in accordance with the present invention.

FIG. 2 illustrates a cross section view showing a LED chip assembly in accordance with the present invention.

### DESCRIPTION OF THE PREFERRED EMBODIMENT

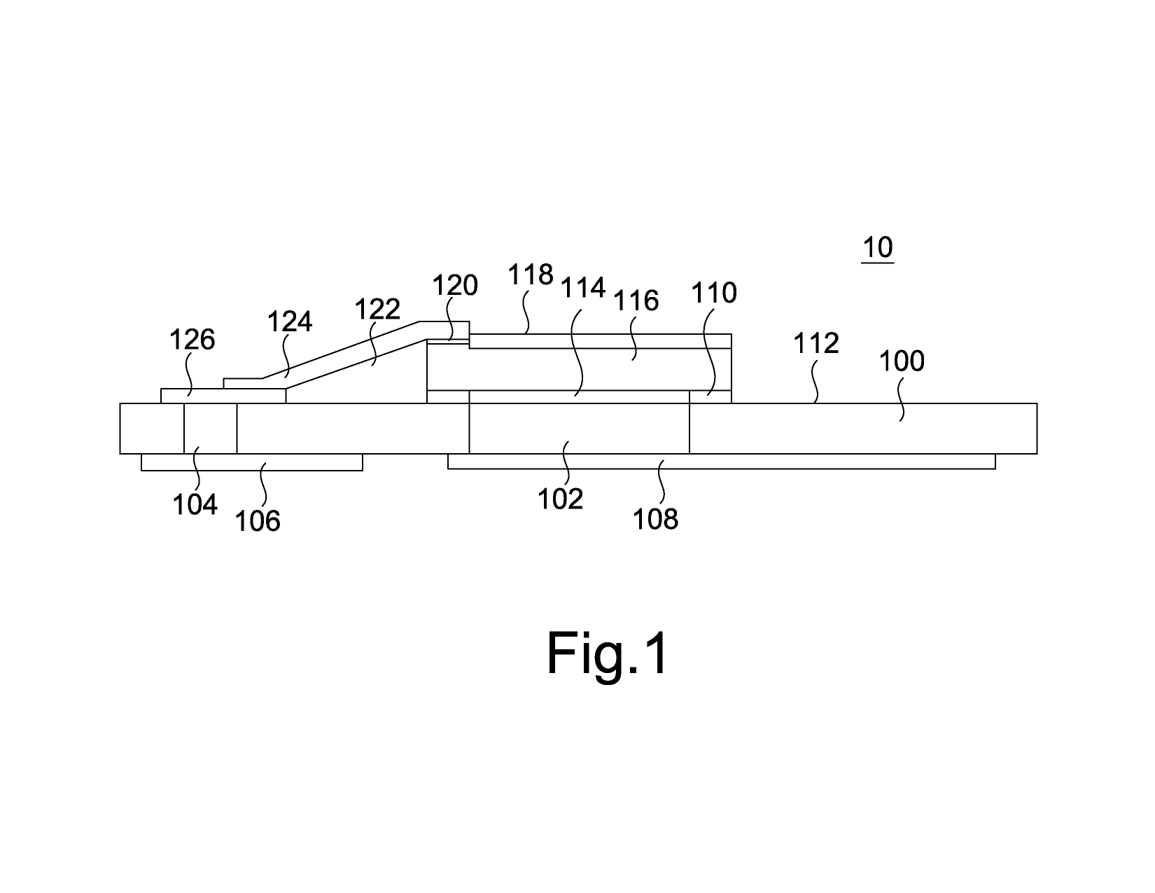

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims. The present invention discloses a LED package assembly which includes LED die, conductive trace and metal inter-connecting as shown in FIG. 1. The invention concept also can be applied to the IC packaging, especially for the power device.

FIG. 1 is cross-sectional view of a LED package 10 having a substrate 100 with predetermined through-holes 102 and 104 formed therein. The substrate 100 could be a metal, glass, ceramic, silicon, plastic, BT, FR4, FR5 or PI etc. The thickness of the substrate 100 is around 40-200 micron-meters. It could be a single or multi-layer (wiring circuit) substrate. The reflection layer 112 may reflect the light emitting from the die. Therefore, the present invention may improve the light emitting efficiency.

A LED device 116 with vertical pads is subsequently adhesion on the upper surface of the substrate 100 by the adhesive layer 110. The adhesive layer 110 maybe only cover the chip size area. The first conductive type (P-type or N-type) pad 120 and the second type (P-type or N-type) pad 114 are respectively formed upper and lower surfaces of the die 116, as shown in FIG. 1. The P-type pad refers to the pad for the P-type conductive material of the LED, and the N-type pad refers to the pad for the N-type conductive material of the LED. As shown in FIG. 1, the LED device 116 faces up to the substrate 100 and allow the first conductive type pad 120 and second conductive type pad 114 both are arranged vertically. The P/N film 118 for emitting light is arranged on the upper surface of the die 116. The reflective conductive layer 112 can be silver, copper, alumina, titanium, organic film and the any combination thereof.

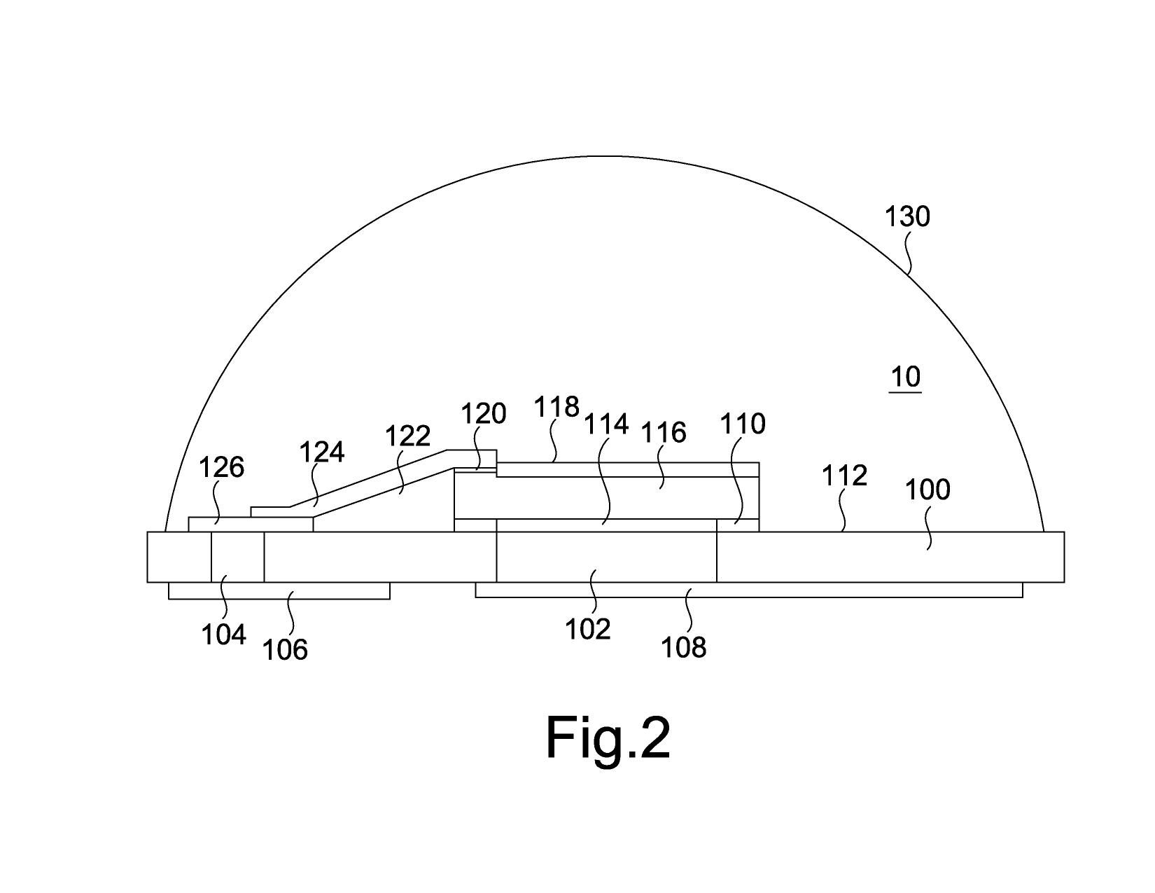

A photo-resist layer (not shown) is patterned by lithography process to form a desired circuit pattern on the backside surface of the substrate 100 to act as the thermal pads or terminal pads 108, 106. A refilling material is formed within the through-holes 102, 104 to form the conductive through hole structures. Terminal pads refilling material 108, 106 are also defined on the backside surface of the substrate and some of them may be connected to the refilling material through holes 102, 104 as shown in FIG. 1. After the traces are defined, the photo-resist layer is stripped away by solution. The deposition of the refilling material for the through-holes 102, 104 is preferably formed by the E-plating process as know in the art. A lens 130 for the LED package 10 is attached on the upper surface of the substrate 100 to cover the entire LED die 112 and major portion of the substrate 100, please refer to FIG. 2. The lens 130 maybe coated with phosphor.

The through holes can be formed within the substrate 100 by laser, mechanical drill, or etching. The P-type and the N-type pads 114, 120 may be coupled to the terminal pads 106, 108 via the refilling material through holes 102, 104. As shown in the illustrations, the refilling material through holes (also refer to interconnecting structures) 102, 104 are coupled to the N, P-type pads and the terminal pads 106, 108. Traces (not shown) may be configured on the lower or upper surface of the substrate 100. The present invention may squeeze the size of the package. In one example, the P, N type pads are formed on LED's lower surface. Thus, the emitting light will not be blocked by the pads 108, 106 at all. The size of the open window of the through hole 102 is smaller than the LED die size. The LED die is typically picked and placed on the substrate with die face up configuration on the attaching material 110 by tool, followed by curing the attaching material.

Please refer to FIGS. 1 and 2, a slanting structure 122 is formed adjacent at least one side of the LED die 116 for carrying conductive traces. The conductive traces 124 is formed on the upper surface of the slanting structure 122 to offer smoother path between the pads 120 and the metal pad 126 over the interconnecting structures 104. The active area refers to the region with P-N layers 118 of the LED. The LED device 116 is formed over the second conductive type pad 114 and the terminal pad 108 is coupled to the second conductive type pad 114 by the interconnecting structure 102. The first conductive type pad 120 is formed on the die 116 and is connected to the metal pad 126, through the traces 124 over the slanting structure 122, and coupling to the terminal pads 106 through the interconnecting structure 104. The arrangement and configuration may offer simpler and smoother signal traces for the LED, thereby improving the performance of the device. The slanting structure 122 with RDL may replace the conventional bonding wires structure to provide better strength for better reliability in thermal stress condiction. The dielectric layer for the slanting structure is dry film type, and is formed under the vacuum, high temperature and bonding condition, for instance, the die thickness is 100 um, and dry film is 35 um, once the dry film is formed on the top of die under the high vacuum and high temperature condition, then, the dry film will flow to the die edge with the elastic property of the material, it will force the dry film to fill out the slope area adjacent to the die. The condition as following: vacuum 1E-1 to 1E-2 torr; temperature ˜70 to 110 centigrade.

The present invention may employ the conventional LED with sapphire substrate with or without the reflection layer under the LED. The reflection layer 112 will be formed on the upper surface of the substrate 100 by sputtering processes or coating organic film, simple material and low cost for the LED package. The refilling material in the through holes and terminal pads offer shorter distance for signal transmission, and better thermal conductivity. The emitting light may fully radiate out of the LED and less reflection loss is achieved. The thermal metal pads are easy to be formed; it offers lowest thermal resistance. Alternative, the refilling material by plating is formed by sputtering, E-plating the Cu/Ni/Au. The LED die 116 with vertical pads, LED die substrate is Si, SiC, AlN etc. The LED die face up on BT substrate and the RDL (re-distribution layer) is formed on both side (top and bottom). The BT substrate has conductive through hole and contact metal pads.

Although preferred embodiments of the present invention have been described, it will be understood by those skilled in the art that the present invention should not be limited to the described preferred embodiment. Rather, various changes and modifications can be made within the spirit and scope of the present invention, as defined by the following Claims.

1. A LED package comprising:
a substrate with a first conductive type through-hole and a second conductive type through-hole through said substrate;
a reflective layer formed on an upper surface of said substrate;
a LED die having first conductive type pad and second conductive type pad, wherein said first conductive type pad is aligned with said first conductive type through-hole, wherein said first conductive type pad and said second conductive type pad are respectively formed on lower and upper surfaces of said LED die;
a slanting structure formed adjacent at least one side of said LED die for carrying conductive traces; and
a conductive trace formed on upper surface of said slanting structure to offer path between said second conductive type pad of said LED die and said second conductive type through-hole of said substrate.

2. The LED package of claim 1, further comprising a refilling material within said first conductive type through-hole and said second conductive type through-hole.

3. The LED package of claim 1, further comprising a lens formed over said upper surface of said substrate to cover said LED die and said lens having phosphor material.

4. The LED package of claim 1, further comprising a first conductive type terminal pad under said substrate and coupled to said first conductive type pad; a second type terminal pad under said substrate and coupled to said second conductive type pad.

5. The LED package of claim 1, wherein said LED die comprises a P/N film formed over said LED die substrate.

6. The LED package of claim 1, wherein said reflective layer includes organic film, metal or alloy.

7. The LED package of claim 6, wherein said reflective layer comprises Ag, Al or Au.

8. The LED package of claim 1, wherein said LED die includes sapphire, Si, SiC or AlN substrate.

9. The LED package of claim 2, wherein said refilling material for said first conductive type through-hole and said second conductive type through-hole comprises Alumina, Titanium, Copper, Nickel or Silver.

10. The LED package of claim 9, wherein said refilling material comprises Cu/Ni/Au.
